(19) United States
(12) Patent Application Publication
(10) Pub. No.: US 2025/0006540 A1
(43) Pub. Date: Jan. 2, 2025

(54) ELECTROSTATIC CHUCK

(71) Applicant: TOTO LTD., Fukuoka (JP)

(72) Inventors: Tetsuro ITOYAMA, Fukuoka (JP); Jumpei UEFUJI, Fukuoka (JP); Tomoki UMETSU, Fukuoka (JP)

(73) Assignee: TOTO LTD., Fukuoka (JP)

(21) Appl. No.: 18/753,835

(22) Filed: Jun. 25, 2024

(30) Foreign Application Priority Data
Jun. 29, 2023 (JP) 2023-106614
Nov. 27, 2023 (JP) 2023-199784
Dec. 25, 2023 (JP) 2023-218249
May 13, 2024 (JP) 2024-078103

(51) Int. Cl. H01L 21/683; C23C 16/458

(52) U.S. Cl. CPC H01L 21/6833; C23C 16/4583

(57) ABSTRACT

An electrostatic chuck includes a dielectric substrate, a base plate which is a metallic member joined to the dielectric substrate and in which a gas hole is formed, and a vent plug arranged inside the gas hole. The vent plug has a porous section which is a section made of a porous ceramic with air permeability, and a dense section which is a section made of a dense ceramic without air permeability, and which surrounds a whole circumference of the porous section from an outer circumference side. The porous section and the dense section are formed together into one piece by sintering without sandwiching a joining material made of a material other than a ceramic.

### CROSS-REFERENCE TO RELATED APPLICATIONS

This application is based on and claims the benefit of priorities of Japanese Patent Application No. 2023-106614 filed Jun. 29, 2023, Japanese Patent Application No. 2023-199784 filed Nov. 27, 2023, Japanese Patent Application No. 2023-218249 filed Dec. 25, 2023, and Japanese Patent Application No. 2024-78103 filed May 13, 2024, which are hereby incorporated by reference herein in their entirety.

### BACKGROUND

The present invention relates to an electrostatic chuck.

In a semiconductor manufacturing apparatus such as a chemical vapor deposition (CVD) apparatus, an electrostatic chuck is provided as an apparatus for attracting and holding a wafer such as a silicon wafer to be processed. The electrostatic chuck includes a dielectric substrate to which an attraction electrode is provided, and a base plate which supports the dielectric substrate, and has a configuration in which these are joined to each other. When a voltage is applied to the attraction electrode, an electrostatic force is generated, and the wafer placed on the dielectric substrate is attracted and held.

An inert gas such as helium is supplied to a space between the dielectric substrate and the wafer for a purpose of temperature regulation or the like of the wafer during a process. For example, as described in Japanese Patent Laid-Open No. 2020-109806, the inert gas is supplied to the above-described space via a gas hole formed in each of the base plates and the dielectric substrate.

During the process of the wafer, potentials of the wafer and a surrounding area of the wafer increase along with plasma injection, voltage application to the attraction electrode, or the like. On the other hand, a potential of the base plate is maintained at a same potential (for example, a ground potential) as that of a peripheral member which constitutes the semiconductor manufacturing apparatus. For this reason, electrical breakdown is likely to occur between an inner face of the gas hole, in particular, in the base plate and a high potential part. When part of plasma flows into an inner side of the gas hole, such electrical breakdown as described above is more likely to occur.

In view of the above, for example, as described in Japanese Patent Laid-Open No. 2020-109806, a porous plug configured to avoid the electrical breakdown is arranged inside the gas hole in the base plate. The porous plug is, for example, a porous member made of an insulating material such as a ceramic. By arranging the porous plug in the gas hole, air permeability can be maintained, and a withstand voltage can also be increased.

When the entire porous plug is constituted by the porous member, since an inner face of the gas hole which is made of a metal is exposed to an internal space of the gas hole via the porous member, there is a possibility that the withstand voltage is not to be sufficiently secured. As measures to reliably avoid the electrical breakdown in the inner face of the gas hole, it is conceivable as described in Japanese Patent Laid-Open No. 2020-109806 that an outer circumference side of the porous member is covered by a dense tubular member. However, since each of the porous member and the tubular member is an individually manufactured ceramic member, it is conceivable that a gap is formed between the porous member and the tubular member due to dimensional tolerances or the like. The gap may serve as a path of the electrical breakdown towards the base plate, which is not advantageous.

To remove the above-described gap, it is also conceivable to use an adhesive to join an outer circumferential surface of the porous member and an inner circumferential surface of the tubular member. However, when such a configuration is adopted, part of an uncured (that is, liquid) adhesive intrudes to an inside of the porous member during adhesion to be then cured. As a result, a new issue occurs that a cross sectional area of a flow path inside the porous member decreases, and furthermore, the area is not to be constant, so that a variation in a flow rate of the gas supplied to the wafer side through a vent plug increases.

The present invention has been made in view of the above-described issue, and is aimed to provide an electrostatic chuck which can avoid electrical breakdown in a gas hole by a vent plug, and also reduce a variation in a flow rate of a gas.

### SUMMARY

To address the above-described issue, an electrostatic chuck according to an aspect of the present invention includes a dielectric substrate in which a first gas hole is formed, a base plate which is a metallic member joined to the dielectric substrate and in which a second gas hole connected to the first gas hole is formed, and a vent plug arranged inside the second gas hole. The vent plug has a porous section which is a section made of a porous ceramic with air permeability, and a dense section which is a section made of a dense ceramic without air permeability, and which surrounds a whole circumference of the porous section from an outer circumference side. The porous section and the dense section are formed together into one piece by sintering without sandwiching a joining material made of a material other than a ceramic.

In the electrostatic chuck with the above-described configuration, the vent plug is not entirely formed of the porous section, and the vent plug further includes the dense section which surrounds the whole circumference of the porous section from the outer circumference side. When the dense section is caused to be present between an inner face of the second gas hole and the porous section, electrical breakdown to the inner face of the second gas hole can be avoided.

Since the porous section and the dense section are formed together into one piece by sintering, no gap exists between the porous section and the dense section. For this reason, the electrical breakdown towards the base plate through the gap does not occur.

Furthermore, a joining material such as, for example, an adhesive is not present between the porous section and the dense section. For this reason, a cross sectional area of a flow path in the porous section does not decrease along with intrusion of the adhesive, and a flow rate of a gas which flows through the vent plug does not vary.

It is noted that the porous section and the dense section may be directly connected to each other without intermediation of a particular joining material, but may be connected via a joining material made of a ceramic material. In either case, it suffices when a whole of the porous plug including the porous section and the dense section is formed into one piece by sintering.

According to the aspect of the present invention, it is possible to provide the electrostatic chuck which can avoid the electrical breakdown in the gas hole by the vent plug, and also reduce the variation in the flow rate of the gas.

### BRIEF DESCRIPTION OF THE DRAWINGS

FIG. 1 is a cross sectional view schematically illustrating a configuration of an electrostatic chuck according to a first embodiment;

FIG. 2 is an enlarged view of a configuration of a vent plug and a neighboring part of the vent plug in the electrostatic chuck in FIG. 1;

FIG. 3A and FIG. 3B illustrate configurations of the vent plug;

FIG. 4A and FIG. 4B are diagrams for describing an issue in a case where the vent plug according to a comparative example is used;

FIG. 5 is a cross sectional view schematically illustrating a configuration of the electrostatic chuck according to a second embodiment;

FIG. 6 is an enlarged and detailed view illustrating a part of the configuration of the electrostatic chuck in FIG. 5;

FIG. 7A and FIG. 7B are cross sectional views illustrating configurations of the electrostatic chuck according to a comparative example of the second embodiment;

FIG. 8 is an enlarged view illustrating a part of a configuration of the electrostatic chuck according to a third embodiment;

FIG. 9 is an enlarged view illustrating a part of a configuration of the electrostatic chuck according to a fourth embodiment; and

FIG. 10 is an enlarged view illustrating a part of a configuration of the electrostatic chuck according to a fifth embodiment.

### DETAILED DESCRIPTION OF THE INVENTION

Hereinafter, the present embodiment will be described with reference to the accompanying drawings. To facilitate understanding of the description, same components in the respective drawings are denoted by same reference signs as much as possible to omit repeated description.

A first embodiment will be described. An electrostatic chuck 10 according to the present embodiment is configured to attract and hold a wafer W set as a process target by an electrostatic force inside a semiconductor manufacturing apparatus which is not illustrated in the drawing such as, for example, an etching apparatus or a CVD film formation apparatus. The wafer W is, for example, a silicon wafer. The electrostatic chuck 10 may be used in an apparatus other than the semiconductor manufacturing apparatus.

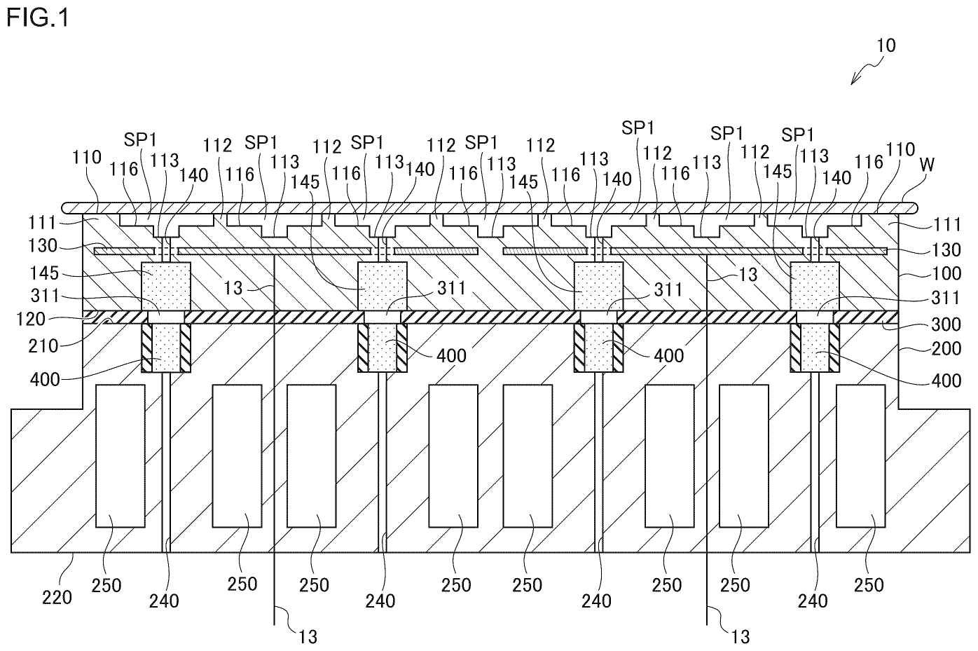

FIG. 1 is a cross sectional view schematically illustrating a configuration of the electrostatic chuck 10 in a state in which the wafer W is attracted and held. The electrostatic chuck 10 includes a dielectric substrate 100, a base plate 200, and a joining layer 300.

The dielectric substrate 100 is a substantially disk-shaped member formed of a ceramic sintered body. The dielectric substrate 100 contains, for example, highly pure aluminum oxide (Al₂O₃), but may contain other materials. A ceramic purity or type, an additive, or the like in the dielectric substrate 100 may be appropriately set by taking into account plasma resistance or the like needed for the dielectric substrate 100 in the semiconductor manufacturing apparatus.

A surface 110 on an upper side in FIG. 1 in the dielectric substrate 100 serves as a “placement surface” on which the wafer W is placed. A surface 120 on a lower side in FIG. 1 in the dielectric substrate 100 serves as a “surface to be joined” which is joined to the base plate 200 via the joining layer 300 described below. A viewpoint in a case where the electrostatic chuck 10 is viewed from the surface 110 side along a direction perpendicular to the surface 110 will be hereinafter also represented as a “top view”.

An attraction electrode 130 is embedded inside the dielectric substrate 100. The attraction electrode 130 is, for example, a thin planar layer made of a metallic material such as tungsten, and is arranged so as to be parallel to the surface 110. In addition to tungsten, as a material of the attraction electrode 130, molybdenum, platinum, palladium, or the like may be used. When a voltage is applied to the attraction electrode 130 from an outside via a feed line 13, an electrostatic force is generated between the surface 110 and the wafer W, and according to this, the wafer W is attracted and held. The attraction electrode 130 may include two attraction electrodes provided as so-called “bipolar” electrodes as in the present embodiment, but also the single attraction electrode 130 may be provided as so-called a “monopolar” electrode.

In FIG. 1, the entire feed line 13 is simplified for illustration. A part of the feed line 13 inside the dielectric substrate 100 is constituted, for example, as an elongated via (hole) filled with a conductive material, and an electrode terminal which is not illustrated in the drawing is provided at a lower end of the via. A part of the feed line 13 which penetrates through the base plate 200 described below is a conductive metallic member (for example, a busbar) with one terminal connected to the above-described electrode terminal. A through hole which is not illustrated in the drawing and into which the feed line 13 is inserted is formed in the base plate 200. For example, a cylindrical insulating member may be provided between an inner face of the through hole and the feed line 13.

As illustrated in FIG. 1, a space SP1 is formed between the dielectric substrate 100 and the wafer W. When a process such as a film formation is performed in the semiconductor manufacturing apparatus, a helium gas for temperature regulation is supplied to the space SP1 from the outside via a gas hole 140 described below or the like. When the helium gas is caused to be present between the dielectric substrate 100 and the wafer W, a thermal resistance between the dielectric substrate 100 and the wafer W is regulated, and according to this, a temperature of the wafer W is maintained at an appropriate temperature. It is noted that the gas for temperature regulation to be supplied to the space SP1 may be a gas of a type different from helium.

A seal ring 111 and a dot 112 are provided on the surface 110 which serves as an attraction surface, and the space SP1 is formed around the seal ring 111 and the dot 112.

The seal ring 111 is a wall that defines the space SP1 in a position corresponding to an outermost circumference. An upper end of the seal ring 111 becomes a part of the surface 110, and abuts against the wafer W. It is noted that the seal ring 111 may include a plurality of seal rings 111 provided so as to divide the space SP1. With such a configuration, a pressure of the helium gas in each of the spaces SP1 can be individually regulated, and a surface temperature distribution of the wafer W during the process can be set to be close to uniformity.

A part denoted by a reference sign “116” in FIG. 1 is a bottom of the space SP1. Hereinafter, this part may also be referred to as a “bottom 116”. The seal ring 111 is formed as a result of digging a part of the surface 110 to a position of the bottom 116 together with the dot 112 described next.

The dot 112 is a circular protrusion which protrudes from the bottom 116. The dot 112 includes a plurality of dots 122 to be provided. The plurality of dots 122 are substantially uniformly distributed and arranged on the placement surface of the dielectric substrate 100. An upper end of each of the dots 112 becomes a part of the surface 110, and abuts against the wafer W. By providing the plurality of thus configured dots 112, warping of the wafer W is reduced.

A trench 113 is formed at the bottom 116 of the space SP1. The trench 113 is a trench formed so as to further retreat from the bottom 116 to the surface 120 side. The trench 113 is formed to aim at quickly diffusing the helium gas supplied from the gas hole 140 into the space SP1 to set a pressure distribution in the space SP1 to be substantially uniform in a short period of time.

The gas hole 140 which perpendicularly extends from the surface 120 towards the surface 110 side is formed in the dielectric substrate 100. An end of the gas hole 140 on the surface 110 side is opened at a bottom of the trench 113. The gas hole 140 includes a plurality of gas holes 140 to be formed in the dielectric substrate 100. The gas holes 140 are lined up along the trenches 113. The gas hole 140 constitutes a part of a flow path for supplying a gas into the space SP1, and is connected to the space SP1 at the bottom of the trench 113. When the space SP1 is divided into a plurality of spaces SP1 by the seal rings 111, one or more gas holes 140 are formed to be connected to each of the divided spaces SP1. The gas hole 140 corresponds to a “first gas hole” in the present embodiment.

As illustrated in FIG. 1, a part of the gas hole 140 on the surface 120 side is expanded in diameter as compared with a part on the surface 110 side, and a vent plug 145 is arranged inside the part of the gas hole 140 on the surface 120 side. The vent plug 145 is, for example, a porous body made of alumina, and the entire vent plug 145 has air permeability. By arranging the above-described vent plug 145 on an inner side of the gas hole 140, a flow of the gas in the gas hole 140 can be secured, and also occurrence of electrical breakdown in a route through the gas hole 140 can be reduced.

The base plate 200 is a substantially disk-shaped metallic member which supports the dielectric substrate 100. The base plate 200 is made, for example, of a metallic material such as aluminum. A surface 210 on the upper side in FIG. 1 in the base plate 200 serves as a “surface to be joined” which is joined to the dielectric substrate 100 via the joining layer 300.

As illustrated in FIG. 1, a gas hole 240 is formed which perpendicularly extends from the surface 210 towards a surface 220 side on an opposite side of the surface 210 in the base plate 200. The gas hole 240 is formed in each of positions overlapping with the gas holes 140 of the dielectric substrate 100 in the top view, and communicates with the gas hole 140 via a through hole 311 provided in the joining layer 300. The gas hole 240 constitutes a part of the flow path for supplying the helium gas towards the space SP1 together with the gas hole 140 of the dielectric substrate 100. The gas hole 240 corresponds to a “second gas hole” in the present embodiment.

It is noted that the gas hole 240 may be formed such that the entire gas hole 240 linearly extends as in the present embodiment, but the gas hole 240 may be formed so as to bend on a way to the surface 220. Such a configuration may also be adopted that the gas holes 240 on the surface 210 side are consolidated in a small number of flow paths inside the base plate 200, and those flow paths extend to the surface 220 side.

As illustrated in FIG. 1, a part of the gas hole 240 on the surface 210 side is expanded in diameter as compared with a part on the surface 220 side, and a vent plug 400 is arranged inside the part of the gas hole 240 on the surface 210 side. Similarly, as in the vent plug 145, the vent plug 400 is a member provided to aim at reducing the occurrence of the electrical breakdown, but has a configuration different from that of the vent plug 145. A specific configuration of the vent plug 400 will be described below.

A coolant flow path 250 through which a coolant flows is formed inside the base plate 200. When a process such as film formation is performed in the semiconductor manufacturing apparatus, the coolant is supplied from the outside to the coolant flow path 250, and according to this, the base plate 200 is cooled down. Heat generated in the wafer W during the process is transferred to the coolant via the helium gas in the space SP1, the dielectric substrate 100, and the base plate 200, and the heat is exhausted to the outside together with the coolant.

An insulating film may be formed on a surface of the base plate 200. The insulating film may be formed so as to cover only a part of the surface of the base plate 200 instead of the entire surface. For example, the insulating film may be formed so as to cover only side parts excluding the surface 210 and the surface 220, that is, exposed parts which are exposed to plasma or the like inside the semiconductor manufacturing apparatus. As a configuration different from the above, the insulating film may be formed so as to cover a range including at least the entire surface 210. As the insulating film, for example, an alumina film formed by thermal splaying can be used. When the surface of the base plate 200 is covered by the insulating film, it is possible to increase a withstand voltage of the base plate 200.

The joining layer 300 is a layer provided between the dielectric substrate 100 and the base plate 200 to join those components. The joining layer 300 is obtained by causing an adhesive made of an insulating material to be cured. According to the present embodiment, a silicone adhesive is used as the above-described adhesive. It is noted however that the joining layer 300 may be obtained by causing an adhesive of other types to be cured. In any case, as the material of the joining layer 300, a material with a highest possible thermal conductivity may be used such that a thermal resistance between the dielectric substrate 100 and the base plate 200 decreases.

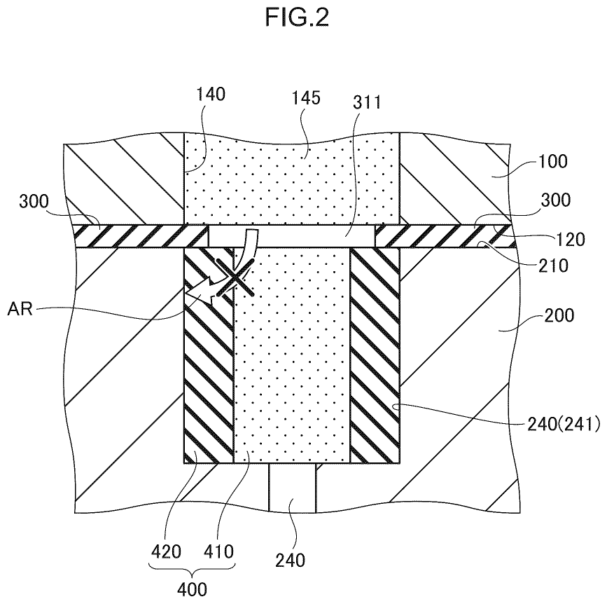

The specific configuration of the vent plug 400 provided in the gas hole 240 will be described. FIG. 2 is an enlarged view of the configuration of the vent plug 400 and a neighboring part of the vent plug 400 in FIG. 1.

As described before, the part of the gas hole 240 on the surface 210 side is expanded in diameter as compared with the part on the surface 220 side, and the vent plug 400 is arranged in this part with the expanded diameter. The part of the gas hole 240 which is expanded in diameter will be hereinafter also referred to as an “expanded diameter portion 241”. The expanded diameter portion 241 is a space of a substantially columnar shape, and a central axis of the expanded diameter portion 241 is perpendicular to the surface 210.

The vent plug 400 is a columnar-shaped member, and a shape of the vent plug 400 is approximately the same as a shape of an internal space of the expanded diameter portion 241. That is, a central axis of the vent plug 400 matches the central axis of the expanded diameter portion 241, and a diameter of an outer circumferential surface of the vent plug 400 is approximately equal to a diameter of an inner circumferential surface of the expanded diameter portion 241.

The vent plug 400 has a porous section 410 and a dense section 420.

The porous section 410 is a section made of a porous ceramic with air permeability. The gas passing through the gas hole 240 is supplied to the space SP1 through the porous section 410 in the vent plug 400. A porosity of the porous section 410 is appropriately set according to a balance between air permeability demanded for gas supply to the space SP1 and a necessary withstand voltage. According to the present embodiment, the porous section 410 is made of a same porous alumina as the vent plug 145, but may be made of other ceramic materials. The porous section 410 has a columnar shape, and a central axis of the porous section 410 matches the central axis of the entire vent plug 400.

The dense section 420 is a section made of a dense ceramic without air permeability. That is, the dense section 420 serves as a section through which a gas does not pass in the vent plug 400. The dense section 420 is made of alumina according to the present embodiment, but may be made of other ceramic materials. In addition, a ceramic material of which the porous section 410 is made and a ceramic material of which the dense section 420 is made may be a same type with each other as in the present embodiment, but may be materials of mutually different types.

The dense section 420 has a cylindrical shape, and a central axis of the dense section 420 matches the central axis of the entire vent plug 400. The porous section 410 described above is accommodated in an inner side of the dense section 420. A dimension of the dense section 420 in an up and down direction in FIG. 2 is the same as a dimension of the porous section 410 in the same direction. In this manner, the dense section 420 surrounds a whole circumference of the porous section 410 from an outer circumference side. In addition, an overall shape of the vent plug 400 including the porous section 410 and the dense section 420 is a columnar shape as described before.

The porous section 410 and the dense section 420 are formed into one member instead of being independent members which can be separated from each other. The porous section 410 and the dense section 420 are formed together into one piece by sintering with being manufactured according to a method described below.

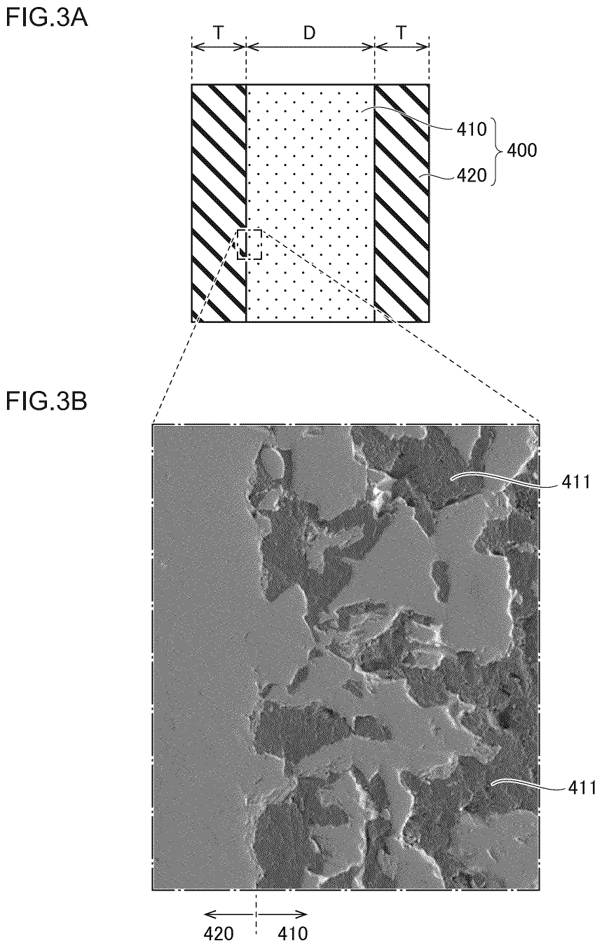

Similarly as in FIG. 2 or the like, FIG. 3A illustrates a cross section in a case where the vent plug 400 is cut along a plane passing through the central axis of the vent plug 400. FIG. 3B illustrates an example of an image obtained by observing a part of the cross section, specifically, a boundary part between the porous section 410 and the dense section 420, by using an electron microscope. A part denoted by reference sign “411” in FIG. 3B is a cross section of air holes formed in the porous section 410.

In the present specification, a phrase “formed together into one piece by sintering” refers to a state in which ceramics particles constituting the dense section 420 and ceramics particles contained in the porous section 410 are joined directly or via a grain boundary as exemplified in FIG. 3B. Specifically, only Al₂O₃ that is a ceramic material constituting each of the porous section 410 and the dense section 420 and other impurities (SiO₂) are present in the boundary part between the porous section 410 and the dense section 420, and a joining layer (for example, a silicone adhesive or the like) made of a material other than a ceramic is not present in the boundary part. A whole of the porous section 410 and the dense section 420 is formed as a single ceramics sintered body. The state of being formed together into one piece by sintering can be confirmed, for example, by observing the cross section of the vent plug 400 at 500× magnification by using a scanning electron microscope. As an observation condition, a general observation condition for a ceramics sintered body may be used, and thermal etching or the like may be also carried out where appropriate.

The vent plug 400 is a member configured to reduce the occurrence of the electrical breakdown in the gas hole 240. If such a configuration is adopted that the dense section 420 is not provided on the outer circumference side of the vent plug 400, and the entire vent plug 400 is the porous section 410, an inner face of the expanded diameter portion 241 which is made of a metal is exposed to an internal surface of the gas hole 240 via the porous section 410. For this reason, a probability that the electrical breakdown occurs increases in a route towards the outer circumference side of the vent plug 400 from the dielectric substrate 100 side as indicated by an arrow AR in FIG. 2. In view of the above, according to the present embodiment, by providing the dense section 420 on the outer circumference side of the vent plug 400, the electrical breakdown in the above-described route is avoided.

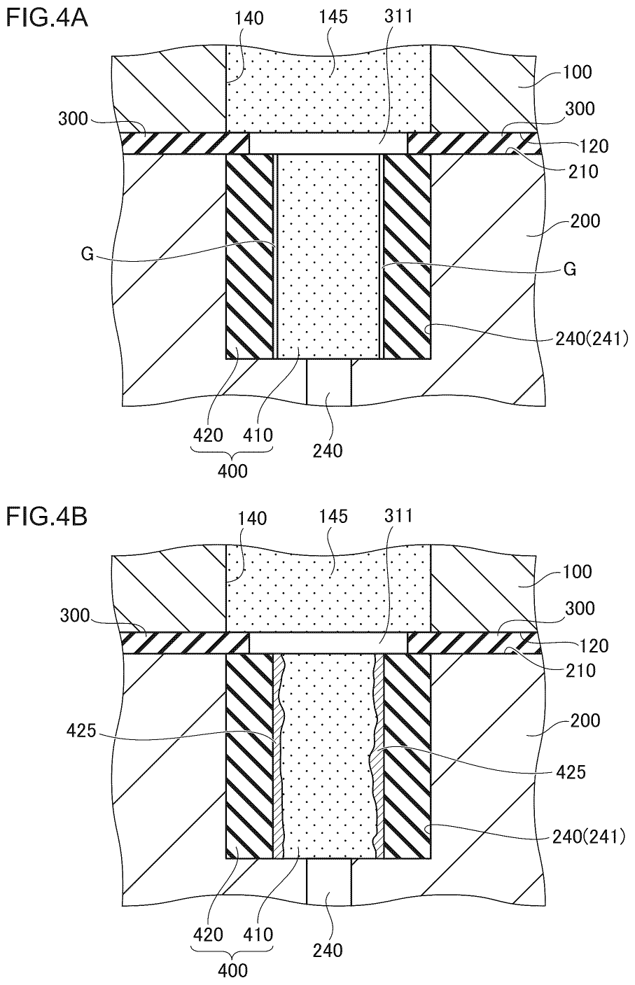

As the configuration of the vent plug 400 for avoiding the electrical breakdown, for example, it is conceivable as in a comparative example illustrated in FIG. 4A that the porous section 410 and the dense section 420 are respectively formed as individual sintered bodies in advance, and both sections are lined up and arranged on an inner side of the expanded diameter portion 241. However, in such a configuration, a minute gap G may be formed between the porous section 410 and the dense section 420 due to dimensional tolerances or the like of both members, and the electrical breakdown may occur in a route along the gap G. In contrast, according to the present embodiment, the porous section 410 and the dense section 420 are formed into a sintered body in one piece, and no gap is formed between those sections, so that the electrical breakdown in the above-described route does not occur.

It is noted that when the porous section 410 and the dense section 420 are respectively formed as individual sintered bodies in advance, and those sections are joined, for example, by the silicone adhesive or the like, the above-described gap G is not formed. However, when the joining is carried out by using the adhesive, part of the uncured (that is, liquid) adhesive intrudes into an inner side from an outer circumferential surface of the porous section 410, and is thereafter cured. FIG. 4B schematically illustrates a region 425 into which the adhesive has intruded in this manner.

In such a state, a cross sectional area of the flow path inside the porous section 410 decreases by an area of the region 425, and furthermore, the area is not to be constant. For this reason, a new issue occurs that the variation in the flow rate of the gas supplied to the space SP1 through the vent plug 400 increases. In contrast, according to the present embodiment, since the adhesive or the like is not present between the porous section 410 and the dense section 420, the entire porous section 410 can be caused to regularly function as the flow path of the gas, and the above-described variation in the flow rate does not occur.

As described above, in the electrostatic chuck 10 of the present embodiment, the electrical breakdown in the gas hole 240 can be avoided by the vent plug 400, and the variation in the flow rate of the gas supplied to the space SP1 can also be reduced.

Instead of the provision of the dense section 420 on the outer circumference side of the porous section 410, it is conceivable that a sprayed film made of alumina or the like is formed so as to cover an outer side surface of the porous section 410. However, since a part of the sprayed film enters the porous section 410, an issue of the decrease in the cross sectional area of the flow path or the variation may be caused similarly as in a comparison example of FIG. 4B. It may be also difficult to sufficiently secure a thickness at which performance of the withstand voltage may be sufficiently demonstrated when the sprayed film is used. Therefore, the present embodiment may still be adopted even as compared with a case where the sprayed film is provided.

According to the present embodiment, each of the porous section 410 and the dense section 420 is made of a high purity alumina ceramic, and both materials have a purity of 92% or more. Since the purity of the material constituting each of the sections is set to be high, an integrity of the vent plug 400 as a whole can be further increased. The purity of the material can be measured by using a mass spectrometry based on inductively coupled plasma (ICP), an elemental analysis based on X-ray fluorescence (XRF), or the like.

A ceramic mean particle size in each of the porous section 410 and the dense section 420 can be optionally set according to a material selection. It is noted however that the ceramic mean particle size in the dense section 420 may be set to be smaller than the ceramic mean particle size in the porous section 410. When the mean particle size in the dense section 420 is set to be small, insulation performance of the dense section 420 can be sufficiently secured. In addition, since the dense section 420 can be formed to be thin, it becomes possible to secure the flow rate of the gas by increasing a diameter of the porous section 410.

A thickness of the dense section 420 is uniform across the whole circumference. The “thickness” mentioned herein refers to a dimension of the dense section 420 along a direction perpendicular to the central axis of the vent plug 400, and is denoted by “T” illustrated in FIG. 3A. When the thickness of the dense section 420 is set to be uniform across the whole circumference, the withstand voltage does not locally decrease in a part along a circumferential direction, and the sufficient withstand voltage can be secured across the whole circumference.

A voltage at 3 kV or more may be applied to the gas hole 240. To reliably avoid the electrical breakdown even in the above-described case, the thickness of the dense section 420 may be secured to be 0.1 mm or more, and may be secured to be 0.3 mm or more. The thickness T of the dense section 420 which is illustrated in FIG. 3A may be secured to be 30% or more of a diameter D of an inner side surface of the dense section 420 (which may also be mentioned as a diameter of the outer side surface of the porous section 410).

According to the present embodiment, the vent plug 400 is in a state of being merely fitted into the expanded diameter portion 241. That is, an outer side surface of the dense section 420 and an inner side surface of the expanded diameter portion 241 are not joined by an adhesive or the like, and a slight gap which is not illustrated in the drawing is formed between those surfaces. However, as illustrated in FIG. 2, an end of the above-described gap on the dielectric substrate 100 side is closed by the joining layer 300. Therefore, the electrical breakdown does not occur via the above-described gap. To realize such a configuration, a diameter of the through hole 311 provided in the joining layer 300 may be set to be larger than the diameter of the inner side surface of the dense section 420 and smaller than a diameter of the outer side surface of the dense section 420.

A method of manufacturing the vent plug 400 will be described. First, both a porous member and a cylindrical molded body are provided. The porous member is a porous ceramic sintered body, and a shape of the porous member is a columnar shape. The porous member is a part which eventually forms the porous section 410.

The cylindrical molded body is a dense ceramic molded body, and a shape of the molded body is a cylindrical shape. That is, a hole of a columnar shape is formed in the cylindrical molded body. The cylindrical molded body is a part which eventually forms the dense section 420. At timing at which both the porous member and the cylindrical molded body are provided, the porous member is already formed into a sintered body, and the cylindrical molded body is a non-sintered molded body. At this time, a diameter of an inner side surface of the cylindrical molded body is slightly larger than a diameter of an outer side surface of the porous member.

Subsequently, the porous member is arranged on an inner side of the hole of the cylindrical molded body. That is, a state is established in which a whole circumference of the porous member is covered by the cylindrical molded body from the outer circumference side. According to this, a whole of the porous member and the cylindrical molded body has a substantially columnar shape. The entire inner side surface of the cylindrical molded body and the entire outer side surface of the porous member face each other, and a gap which is not illustrated in the drawing is formed between those surfaces.

This state is maintained, and the porous member and the cylindrical molded body are baked at the same time. At this time, the cylindrical molded body gradually shrinks due to baking, and the gap between those surfaces becomes zero. That is, the inner side surface of the cylindrical molded body and the outer side surface of the porous member are put into a state of being in close contact without a gap. As a result of the baking performed in the above-described state, the porous member and the cylindrical molded body are joined to each other into one piece, and the whole turns into a single sintered body.

A second embodiment will be described. Hereinafter, a difference from the first embodiment will be mainly described, and a description on a same aspect as the first embodiment will be appropriately omitted.

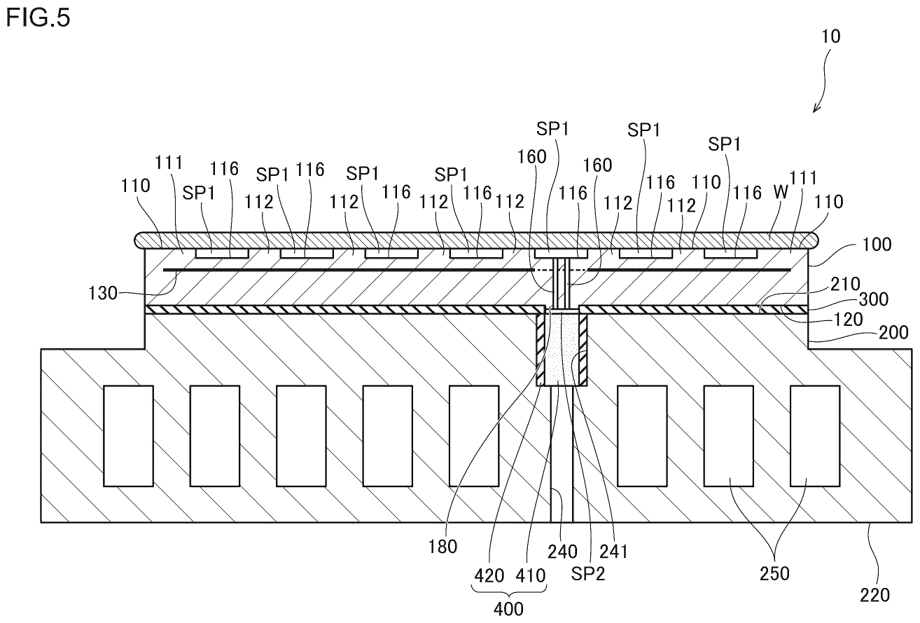

FIG. 5 is a cross sectional view schematically illustrating a configuration of the electrostatic chuck 10 according to the present embodiment similarly as in FIG. 1. According to the present embodiment too, the electrostatic chuck 10 includes the dielectric substrate 100, the base plate 200, and the joining layer 300.

The attraction electrode 130 is embedded inside the dielectric substrate 100. According to the present embodiment, only the single attraction electrode 130 is provided as so-called a “monopolar” electrode. Similarly as in the first embodiment of FIG. 1, the two attraction electrodes 130 may be provided as so-called “bipolar” electrodes. In FIG. 5, illustration of the feed line 13 through which a voltage is applied to the attraction electrode 130 is omitted.

The supply of the helium gas to the space SP1 is performed via a gas hole 160 according to the present embodiment. The gas hole 160 is a through hole formed so as to penetrate through the dielectric substrate 100. The gas hole 160 is formed so as to perpendicularly extend from the bottom 116 towards the surface 120 side. The gas hole 160 may be formed so as to linearly extend as in the present embodiment, but may be formed so as to bend on a way from the bottom 116 to the surface 120. When the plurality of seal rings 111 are provided so as to divide the space SP1, the gas hole 160 may be formed in a position corresponding to each of the plurality of spaces SP1.

According to the present embodiment, the trench 113 is not formed at the bottom 116. Similarly as in the first embodiment, after the trench 113 may be formed at the bottom 116, the gas hole 160 may be formed to be opened at the bottom of the trench 113.

According to the present embodiment, a pair of the gas holes 160 formed in positions close to each other is formed in multiple sets each so as to penetrate through each part of the dielectric substrate 100. In FIG. 5, only one set of the gas holes 160 among those is illustrated. The gas hole 160 corresponds to the “first gas hole” in the present embodiment. A specific configuration of the gas holes 160 and a neighboring part of the gas holes 160 will be described below.

Similarly, as in the first embodiment, the gas hole 240 is formed in the base plate 200. The gas hole 240 is a hole which communicates with the gas holes 160 described above, and is a part of a route for supplying the helium gas towards the space SP1.

The gas hole 240 is formed so as to perpendicularly extend from the surface 210 towards the surface 220 side that is on the opposite side of the surface 210. The gas hole 240 includes a plurality of gas holes 240 to be formed. The single gas hole 240 each is formed in a position corresponding to each set of the gas holes 160 provided in pairs. That is, the two gas holes 160 are connected to the one gas hole 240. The gas hole 240 corresponds to the “second gas hole” in the present embodiment.

The gas hole 240 may be formed so as to linearly extend as in the present embodiment, but may be formed so as to bend on a way from the surface 210 to the surface 220. In either case, it suffices when an opening at an end of the gas hole 160 on the surface 120 side and an opening at an end of the gas hole 240 on the surface 210 side are overlapped with each other in the top view.

As illustrated in FIG. 5, a part of the gas hole 240 in a vicinity of the end on the surface 210 side is the expanded diameter portion 241 with the diameter expanded as compared with other parts. The vent plug 400 having a same configuration as that of the first embodiment is arranged inside the expanded diameter portion 241. By arranging the vent plug 400 on the inner side of the gas hole 240, a flow of the helium gas in the gas hole 240 is secured, and the occurrence of the electrical breakdown in the route through the gas hole 240 is reduced.

The vent plug 400 is a member of a substantially columnar shape, and is arranged on an inner side of the expanded diameter portion 241 in a state in which the central axis of the vent plug 400 matches the central axis of the expanded diameter portion 241. An outer diameter of the vent plug 400 is approximately equal to an inner diameter of the expanded diameter portion 241. The vent plug 400 is press fitted into the expanded diameter portion 241, for example. An end face of the vent plug 400 on the dielectric substrate 100 side is in a same plane as the surface 210 according to the present embodiment.

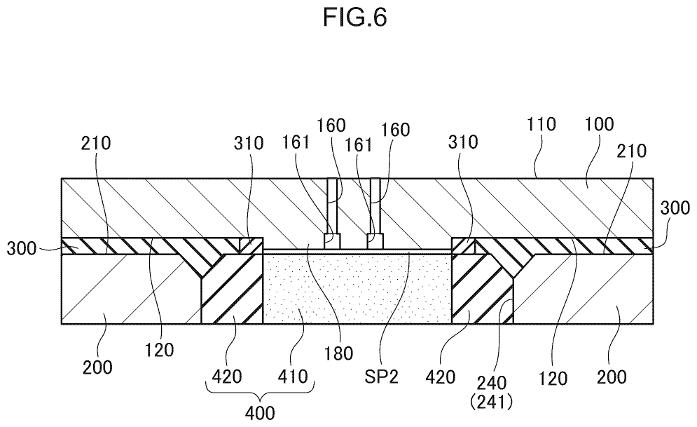

FIG. 6 is an enlarged view illustrating a configuration of the gas holes 160 and a neighboring part of the gas holes 160. It is noted that in FIG. 6, illustration of the dot 112 or the like formed on the surface 110 side is omitted.

As illustrated in FIG. 6, a protruding portion 180 is formed on the surface 120 on the base plate 200 side in the dielectric substrate 100. In the protruding portion 180, a part of the surface 120 protrudes towards the base plate 200 side. A shape of the protruding portion 180 in the top view is circular. Each of the gas holes 160 in pairs formed in the positions close to each other is formed so as to penetrate through the single protruding portion 180.

The protruding portion 180 is integrated with other parts of the dielectric substrate 100 (parts other than the protruding portion 180). The thus configured protruding portion 180 can be formed, for example, by applying a process such as sandblasting to the surface 120 of the dielectric substrate 100.

A central axis of the protruding portion 180 matches the central axis of the entire vent plug 400. An outer diameter of the protruding portion 180 is approximately equal to an outer diameter of the porous section 410.

An annular seal member 310 is arranged between the dielectric substrate 100 and the vent plug 400. The seal member 310 is a member obtained by causing a silicone adhesive, for example, to be cured. An inner diameter of the seal member 310 is approximately equal to the outer diameter of the protruding portion 180. A thickness (dimension along a direction perpendicular to the placement surface) of the seal member 310 is equal to a thickness of the joining layer 300. The seal member 310 is arranged so as to surround a whole circumference of the protruding portion 180 from the outer circumference side. The seal member 310 is a member configured to avoid a situation where during manufacturing of the electrostatic chuck 10, the uncured adhesive which is to turn into the joining layer 300 enters the inner side. The seal member 310 may be a member made of a same material as that of the joining layer 300, but may also be a member made of a different material.

A protruding amount of the protruding portion 180 towards the base plate 200 side is slightly smaller than the thickness of the joining layer 300. For this reason, a space SP2 that is a minute gap is formed between a distal end surface of the protruding portion 180 and the vent plug 400. The space SP2 is a space corresponding to an internal space of the through hole 311 in the first embodiment.

As described above, in the electrostatic chuck 10 of the present embodiment, the protruding portion 180 is formed in the dielectric substrate 100, and the gas hole 160 is formed so as to penetrate through the protruding portion 180.

A reason to adopt such a configuration will be described. During the process of the wafer W, potentials of the wafer W and a surrounding area of the wafer increase along with plasma incidence, voltage application to the attraction electrode 130, or the like. On the other hand, a potential of the base plate 200 is maintained at a same potential (for example, a ground potential) as that of a peripheral member constituting the semiconductor manufacturing apparatus. For this reason, the electrical breakdown in the route through the gas hole 160 or the gas hole 240 is likely to occur.

If the protruding portion 180 is not formed in the dielectric substrate 100, a thickness of the space SP2 becomes equal to the thickness of the joining layer 300. That is, in a part which is in a vicinity of the gas hole 160 or the like and in which the dielectric substrate 100 and the base plate 200 face each other, the space SP2 with a thickness similar to the thickness of the joining layer 300 is formed between the dielectric substrate 100 and the base plate 200. The thickness is, for example, approximately 250 μm. According to the Paschen's law, in the space with the above-described thickness, a pressure of the helium gas inside the gas hole 160 or the like is often in a pressure range where the electrical breakdown is relatively likely to occur.

In view of the above, according to the present embodiment, by forming the protruding portion 180 in the dielectric substrate 100, the thickness of the space SP2 is set to be smaller than the thickness of the joining layer 300. That is, a distance between the dielectric substrate 100 and the base plate 200 (according to the present embodiment, the vent plug 400) which face each other in the position of the gas hole 160 or the like is set to be smaller than the thickness of the joining layer 300. By setting the distance between the dielectric substrate 100 and the base plate 200 to be small to such an extent that the electrical breakdown does not occur, it is possible to sufficiently reduce the electrical breakdown via the gas hole 160 and the space SP2.

It is noted that as a configuration for narrowing the space SP2, it is conceivable that an overall thickness of the joining layer 300 is reduced instead of the formation of the protruding portion 180. However, when the thickness of the joining layer 300 is changed, there is a fear, for example, that a thermal expansion difference between the dielectric substrate 100 and the base plate 200 is not to be absorbed by the joining layer 300. Therefore, as in the present embodiment, the configuration of forming the protruding portion 180 is more preferably adopted without changing the thickness of the joining layer 300.

A mode may be adopted in which the vent plug 400 is not arranged inside the gas hole 240, and the protruding portion 180 directly faces the surface 210 of the base plate 200. In such a mode too, by forming the protruding portion 180 to narrow the space SP2, it is possible to avoid the electrical breakdown. It is noted however that to make the electrical breakdown less likely to occur, the vent plug 400 may be arranged as described in the present embodiment.

The entire vent plug 400 may be, for example, the porous section 410. However, when the configuration is adopted in which the dense section 420 is provided on the outer circumference side of the porous section 410 as in the present embodiment, since an inner face (that is, a metal) of the gas hole 240 is covered by the dense section 420, it is possible to more reliably avoid the occurrence of the electrical breakdown.

As described before, the outer diameter of the protruding portion 180 is approximately equal to the outer diameter of the porous section 410. As a result, the porous section 410 is overlapped with each of the gas holes 160 formed in the protruding portion 180 in the top view. Since the porous section 410 is arranged immediately below the gas holes 160, the supply of the helium gas towards the space SP1 is not hindered more than necessary.

The entire dense section 420 is in a position on an outer side relative to the protruding portion 180 in the top view. In such a configuration, it is possible to cause the seal member 310 which surrounds the protruding portion 180 from the outer circumference side to abut against the dense section 420 across the whole circumference. According to this, it is possible to avoid a situation where the uncured adhesive which is to turn into the joining layer 300 intrudes to the inside of the porous section 410. It is noted that in a portion of the dense section 420 to be arranged in the position on the outer side relative to the protruding portion 180 in the top view may be only a part of the dense section 420 instead of the entirety. That is, an inner diameter of the dense section 420 may be slightly smaller than the outer diameter of the protruding portion 180.

As illustrated in FIG. 6, a part in a vicinity of an end of the gas hole 160 on the base plate 200 side becomes an expanded diameter portion 161 with a diameter expanded more than other parts. That is, an inner diameter at the end of the gas hole 160 on the base plate 200 side is larger than an inner diameter at an end of the gas hole 160 on the placement surface side. By expanding an inner diameter of an inlet part of the gas hole 160 for the helium gas, even when the thickness of the space SP2 is extremely narrow, the flow rate of the helium gas flowing into the gas hole 160 can be secured. A length of the expanded diameter portion 161 may be set to be, for example, a length similar to the thickness of the joining layer 300.

The protruding portion 180 may be formed, for example, by joining another member of a disk shape to the surface 120 of the dielectric substrate 100. However, in view of a possibility of falling off of the protruding portion 180 or the like, the configuration may be adopted where the protruding portion 180 is integrally formed with another part of the dielectric substrate 100 as in the present embodiment. In either case, the protruding portion 180 may be formed as a dense body without air permeability similarly as in the other part of the dielectric substrate 100.

A number of the gas holes 160 penetrating through the single protruding portion 180 may be only one, or may be three or more. As in the present embodiment, when the plurality of gas holes 160 are formed in the single protruding portion 180, the flow rate of the helium gas can be sufficiently secured, and the diameter of each of the gas holes 160 can be set to be small. As a result, it is possible to further reduce the occurrence of the electrical breakdown.

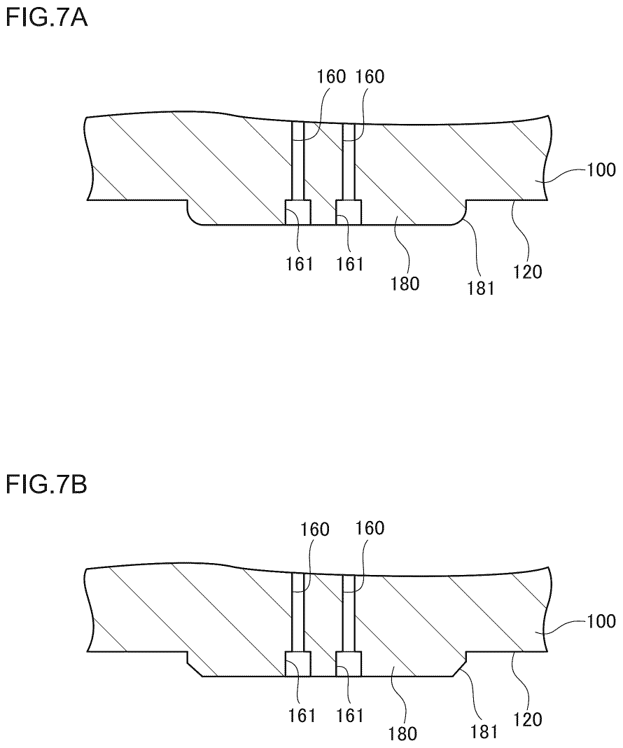

A bevel 181 for avoiding chipping or the like may be applied to a position that becomes an outer circumferential end of the distal end surface in the protruding portion 180. The bevel 181 may be a round as illustrated in FIG. 7A or a chamfer as illustrated in FIG. 7B, for example.

Similarly, as in the first embodiment, the vent plug 400 of the present embodiment has the porous section 410 and the dense section 420, and these sections are formed together into one piece by sintering. Instead of the above-described mode, the porous section 410 and the dense section 420 may be obtained by joining individual members which can be separated from each other by the adhesive or the like to be formed into one piece.

A third embodiment will be described. Hereinafter, a difference from the second embodiment described above will be mainly described, and a description on a same aspect as the second embodiment will be appropriately omitted.

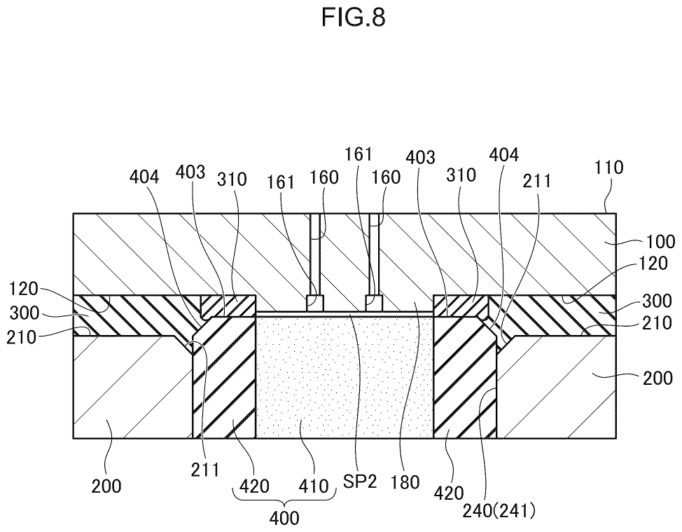

FIG. 8 illustrates a configuration of the electrostatic chuck 10 according to the present embodiment from a viewpoint similar to that of FIG. 6. As illustrated in FIG. 8, the vent plug 400 of the present embodiment extends to a position further on the dielectric substrate 100 side as compared with the second embodiment illustrated in FIG. 6.

For convenience of the description, a surface in the base plate 200 which faces the dielectric substrate 100 via the joining layer 300 will be hereinafter also referred to as a “facing surface”. According to the present embodiment, the surface 210 corresponds to the “facing surface”. Hereinafter, the surface 210 will be also referred to as a “facing surface 210”.

It is noted that even when the surface of the base plate 200 including the surface 210 is covered by the insulating film, the surface 210, not a surface of the insulating film, corresponds to the “facing surface” similarly as in the above-described configuration. In either case, the “facing surface” refers to a surface of the base plate 200 made of a metal which faces the dielectric substrate 100 via the joining layer 300.

As illustrated in FIG. 8, a part of the vent plug 400 of the present embodiment protrudes from the facing surface 210 towards the dielectric substrate 100 side. That is, the protruding portion 180 protrudes from the dielectric substrate 100 towards the space SP2, and the vent plug 400 protrudes from the base plate 200 towards the space SP2. The protruding amount of the vent plug 400 towards the dielectric substrate 100 side is smaller than the thickness of the joining layer 300.

In this manner, by causing both the protruding portion 180 and the vent plug 400 which face each other to protrude towards the space SP2, the thickness of the space SP2 further decreases. According to this, the electrical breakdown via the space SP2 is even less likely to occur.

Another configuration will be described. A beveled portion 211 is formed in a boundary part between the inner face of the expanded diameter portion 241 in the gas hole 240 and the facing surface 210. The beveled portion 211 is such a slanted surface that an inner diameter of the beveled portion 211 increases as the beveled portion 211 further approaches the dielectric substrate 100 side. A part of the joining layer 300 also enters a section between the beveled portion 211 and the dense section 420.

A distal end surface of the vent plug 400 on the dielectric substrate 100 side will be hereinafter also referred to as a “distal end surface 403”. A beveled portion 404 is formed in a part on an outer circumferential side of the distal end surface 403, that is, a boundary part between the outer side surface of the dense section 420 and the distal end surface 403. The beveled portion 404 is such a slanted surface that an inner diameter of the beveled portion 404 decreases as the beveled portion 404 further approaches the dielectric substrate 100 side. The beveled portion 404 may be a chamfer, but may also be a round.

According to the present embodiment too, the annular seal member 310 which surrounds the protruding portion 180 from an outer side is arranged between the vent plug 400 and the dielectric substrate 100. Most of the seal member 310 of the present embodiment is sandwiched between the distal end surface 403 and the surface 120. For this reason, the thickness (dimension along the direction perpendicular to the placement surface) of the seal member 310 is smaller than the thickness of the joining layer 300. By arranging the thus configured seal member 310, intrusion of the joining layer 300 towards an inner side of the seal member 310 is avoided. That is, such a situation is avoided that the uncured adhesive which is to turn into the joining layer 300 intrudes at the time of manufacturing to close the gas hole 160 or the like.

As illustrated in FIG. 8, an edge of the seal member 310 on an outer circumferential side extends to a position immediately above the beveled portion 404. In other words, the seal member 310 in the top view is arranged so as to straddle both the distal end surface 403 and the beveled portion 404.

If the seal member 310 in the top view is overlapped with only the distal end surface 403, at the time of assembly of the electrostatic chuck 10, the entire seal member 310 is compressed by the distal end surface 403. As a result, a force applied from the seal member 310 to the dielectric substrate 100 may become excessive, and the dielectric substrate 100 may be damaged.

In view of the above, according to the present embodiment, such a configuration is adopted that the seal member 310 in the top view straddles both the distal end surface 403 and the beveled portion 404 as described above. In such a configuration, there is a room for a part of the seal member 310 compressed at the time of assembly to escape to a position immediately above the beveled portion 404 which is a relatively wide space. Since the force received by the dielectric substrate 100 decreases as compared with a case where the entire seal member 310 is compressed by the distal end surface 403, the damage to the dielectric substrate 100 can be reduced.

A fourth embodiment will be described. Hereinafter, a difference from the third embodiment described above will be mainly described, and a description on a same aspect as the third embodiment will be omitted.

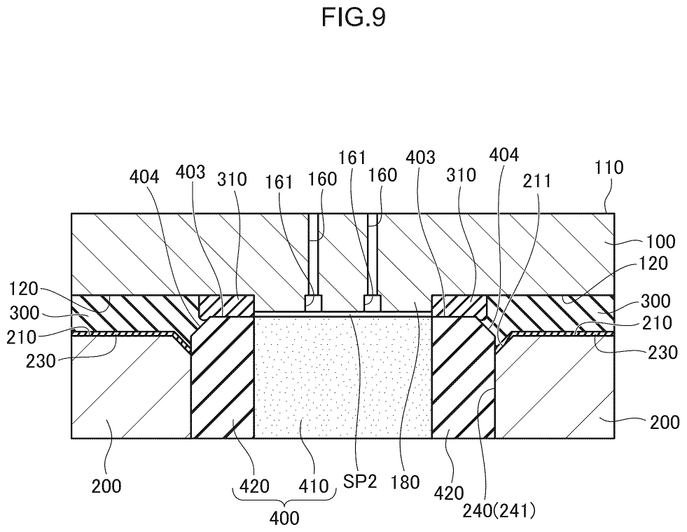

FIG. 9 illustrates a configuration of the electrostatic chuck 10 according to the present embodiment from a viewpoint similar to that of FIG. 6 or FIG. 8. As illustrated in FIG. 9, according to the present embodiment, the surface of the base plate 200 is covered by the insulating film 230. The insulating film 230 is a film made of an insulating material such as, for example, alumina, and is formed by, for example, thermal splaying. The insulating film 230 of the present embodiment is formed so as to cover the facing surface 210 and the beveled portion 211. A range of the base plate 200 covered by the insulating film 230 may be different from the above-described range.

The vent plug 400 of the present embodiment is arranged such that a part of the vent plug 400 protrudes from the surface of the insulating film 230 towards the dielectric substrate 100 side. By arranging the vent plug 400 so as to protrude from not only the facing surface 210 but also the surface of the insulating film 230, it is possible to further decrease the thickness of the space SP2.

It is noted that depending on the thickness of the insulating film 230, the joining layer 300, or the like, a mode may be adopted in which the vent plug 400 protrudes from the facing surface 210 but does not protrude from the surface of the insulating film 230.

A fifth embodiment will be described. Hereinafter, a difference from the third embodiment (FIG. 8) will be mainly described, and a description on a same aspect as the third embodiment will be omitted.

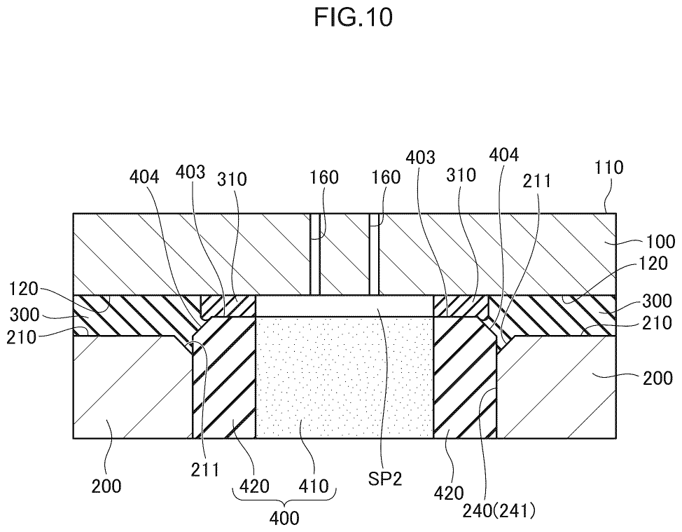

FIG. 10 illustrates a configuration of the electrostatic chuck 10 according to the present embodiment from a viewpoint similar to that of FIG. 8. According to the present embodiment, similarly as in the third embodiment (FIG. 8), a part of the vent plug 400 protrudes from the facing surface 210 towards the dielectric substrate 100 side. On the other hand, the protruding portion 180 is not provided in the dielectric substrate 100 of the present embodiment. In such a configuration too, the electrical breakdown can be avoided by decreasing the thickness of the space SP2.

As the configuration of the vent plug 400, a configuration different from the configuration described in the first embodiment may be adopted. For example, the entire vent plug 400 may be the porous section 410. The same also applies to the other embodiments described thus far.

The present embodiment has been described above with reference to the specific examples, but the present disclosure is not limited to these specific examples. Configurations obtained by adding appropriate design modifications to these specific examples by a person skilled in the art are also within the scope of the present disclosure as long as the configurations have a feature of the present disclosure. Each of the elements included in each of the specific examples described above and arrangements, conditions, shapes, and the like of the elements are not limited to those illustrated and can be modified as appropriate. For each of the elements included in each of the specific examples described above, a combination can be appropriately changed as long as a technical contradiction does not occur.

What is claimed is:

1. An electrostatic chuck comprising:
a dielectric substrate which has a placement surface on which an object to be attracted is placed, and in which a first gas hole is formed;
a base plate which is a metallic member supporting the dielectric substrate, and in which a second gas hole is formed in a position corresponding to the first gas hole; and
a vent plug arranged inside the second gas hole, wherein
the vent plug has
a porous section which is a section made of a porous ceramic with air permeability, and
a dense section which is a section made of a dense ceramic without air permeability, and which surrounds a whole circumference of the porous section from an outer circumference side, and
the porous section and the dense section are formed together into one piece by sintering without sandwiching a joining material made of a material other than a ceramic.

2. The electrostatic chuck according to claim 1, wherein both a ceramic purity in the porous section and a ceramic purity in the dense section are 92% or more.

3. The electrostatic chuck according to claim 1, wherein a ceramic mean particle size in the dense section is smaller than a ceramic mean particle size in the porous section.

4. The electrostatic chuck according to claim 1, wherein a shape of the dense section is a cylindrical shape, and a thickness of the dense section is uniform across a whole circumference.

5. The electrostatic chuck according to claim 4, wherein the thickness of the dense section is 0.1 mm or more.

6. The electrostatic chuck according to claim 1, further comprising:
a joining layer which joins the dielectric substrate and the base plate, wherein
a protruding portion which protrudes towards the base plate is formed in a surface of the dielectric substrate on the base plate side, and
the first gas hole is formed so as to penetrate through the protruding portion.

7. The electrostatic chuck according to claim 6, wherein when viewed from a direction perpendicular to the placement surface, the porous section is overlapped with the first gas hole.

8. The electrostatic chuck according to claim 7, wherein when viewed from the direction perpendicular to the placement surface, at least a part of the dense section is on an outer side relative to the protruding portion.

9. The electrostatic chuck according to claim 6, wherein the first gas hole includes a plurality of first gas holes, and the plurality of first gas holes are formed so as to penetrate through the single protruding portion.

10. The electrostatic chuck according to claim 6, wherein an inner diameter at an end of the first gas hole on the base plate side is larger than an inner diameter at an end of the first gas hole on the placement surface side.

11. The electrostatic chuck according to claim 6, wherein the protruding portion is integrally formed with another part of the dielectric substrate.

12. The electrostatic chuck according to claim 6, wherein
when a surface of the base plate which faces the dielectric substrate via the joining layer is set as a facing surface,
a part of the vent plug protrudes from the facing surface towards the dielectric substrate side.

13. The electrostatic chuck according to claim 12, wherein
the facing surface is covered by an insulating film, and
a part of the vent plug protrudes from a surface of the insulating film towards the dielectric substrate side.

14. The electrostatic chuck according to claim 12, wherein
an annular seal member is arranged between the vent plug and the dielectric substrate, and
intrusion of the joining layer towards an inner side of the seal member is avoided.

15. The electrostatic chuck according to claim 1, further comprising:
a joining layer which joins the dielectric substrate and the base plate, wherein
when a surface of the base plate which faces the dielectric substrate via the joining layer is set as a facing surface,
a part of the vent plug protrudes from the facing surface towards the dielectric substrate side.

16. An electrostatic chuck comprising:
a dielectric substrate which has a placement surface on which an object to be attracted is placed, and in which a first gas hole is formed;
a base plate which is a metallic member supporting the dielectric substrate, and in which a second gas hole is formed in a position corresponding to the first gas hole; and
a joining layer which joins the dielectric substrate and the base plate, wherein
a protruding portion which protrudes towards the base plate is formed in a surface of the dielectric substrate on the base plate side, and
the first gas hole is formed so as to penetrate through the protruding portion.

17. The electrostatic chuck according to claim 16, wherein
a vent plug is arranged inside the second gas hole.

18. The electrostatic chuck according to claim 17, wherein
when a surface of the base plate which faces the dielectric substrate via the joining layer is set as a facing surface,
a part of the vent plug protrudes from the facing surface towards the dielectric substrate side.

19. The electrostatic chuck according to claim 18, wherein
the facing surface is covered by an insulating film, and
a part of the vent plug protrudes from a surface of the insulating film towards the dielectric substrate side.
